(19) United States
(12) Patent Application Publication
(10) Pub. No.: US 2023/0167554 A1
(43) Pub. Date: Jun. 1, 2023

(54) PLASMA PROCESSING APPARATUS AND PLASMA PROCESSING METHOD

(71) Applicant: TOKYO ELECTRON LIMITED, Tokyo (JP)

(72) Inventor: Tatsuo MATSUDO, Tokyo (JP)

(21) Appl. No.: 17/990,022

(22) Filed: Nov. 18, 2022

(30) Foreign Application Priority Data
Nov. 26, 2021 (JP) 2021-192339

(51) Int. Cl. C23C 16/517; C23C 16/455; C23C 16/458; C23C 16/513; C23C 16/505; C23C 16/52

(52) U.S. Cl. CPC C23C 16/517; C23C 16/52; C23C 16/505; C23C 16/513; C23C 16/4582; C23C 16/45565

(57) ABSTRACT

A plasma processing apparatus comprising: a chamber; an upper electrode; a shower head having openings, an inner space of the chamber being divided into a first space and a second space; a shielding part including first and second shielding plates arranged in parallel between the upper electrode and the shower head, the shielding part having through-holes aligned with the openings; a gas supply device configured to supply a gas; a radio frequency (RF) power supply configured to output an RF voltage; a voltage applying part configured to select ions or radicals passing through the through-holes in the plasma by applying a control voltage to the shielding part; and a controller configured to control the voltage applying part by independently applying a control voltage to each of the first and second shield plates depending on control from the controller.

### CROSS-REFERENCE TO RELATED APPLICATIONS

This application claims priority to Japanese Patent Application No. 2021-192339 filed on Nov. 26, 2021, the entire contents of which are incorporated herein by reference.

### TECHNICAL FIELD

Embodiments of the present disclosure relate to a plasma processing apparatus and a plasma processing method.

### BACKGROUND

Plasma processing is performed as an example of substrate processing. In the plasma processing, a substrate is processed by chemical species from plasma produced in a chamber. The chemical species in the plasma include ions and radicals. Since ions can damage the substrate, substrate processing using radicals may be performed. Japanese Laid-open Patent Publication No. 2019 - 203155 discloses a technique for removing ions in remote plasma using an ion trap disposed directly below a shower plate.

### SUMMARY

The present disclosure provides a technique for selectively using ions and radicals in remote plasma.

In accordance with an aspect of the present disclosure, there is a plasma processing apparatus comprising: a chamber; an upper electrode; a shower head disposed below the upper electrode, an inner space of the chamber being divided into a first space between the upper electrode and the shower head and a second space disposed below the shower head, the shower head having a plurality of openings formed therethrough to allow the first space and the second space to communicate with each other; a substrate support configured to support a substrate in the second space; a shielding part disposed between the upper electrode and the shower head, the shielding part including a first shielding plate and a second shielding plate arranged in parallel along the shower head, the second shielding plate being disposed over the shower head, the first shielding plate being disposed over the second shielding plate, each of the first shielding plate and the second shielding plate having a plurality of through-holes arranged to be aligned with the openings of the shower head; a gas supply device configured to supply a gas to a region between the upper electrode and the shielding part in the first space; a radio frequency (RF) power supply configured to output an RF voltage to generate plasma of the gas; a voltage applying part configured to select ions or radicals passing through the through-holes in the plasma by applying a control voltage to the shielding part; and a controller configured to control the voltage applying part; wherein the voltage applying part is configured to independently apply a control voltage to each of the first shield plate and the second shield plate depending on control from the controller.

### BRIEF DESCRIPTION OF THE DRAWINGS

The objects and features of the present disclosure will become apparent from the following description of embodiments, given in conjunction with the accompanying drawings, in which:

FIG. 1 shows a configuration of a plasma processing apparatus according to one embodiment;

FIG. 2 shows a configuration of an exemplary voltage applying part and an exemplary shielding part;

FIG. 3 shows a configuration of an exemplary voltage applying part and an exemplary shielding part;

FIG. 4 shows a circuit configuration of an exemplary pulse generator;

FIG. 5 is a flowchart of a plasma processing method according to one embodiment;

FIG. 6 shows an example of a waveform of an RF voltage applied to an upper electrode;

FIGS. 7 to 11 show examples of voltage waveforms applied to two shielding plates; and

FIG. 12 shows a configuration of an exemplary voltage applying part and an exemplary shielding part in another configuration of a plasma processing apparatus according to one embodiment.

### DETAILED DESCRIPTION

Hereinafter, various embodiments will be described.

In an exemplary embodiment, a plasma processing apparatus is provided. The plasma processing apparatus may comprise a chamber, an upper electrode, a shower head, a substrate support, a shielding part, a gas supply device, a radio frequency (RF) power supply, a voltage applying part, a controller. The shower head may be disposed below the upper electrode. An inner space of the chamber may be divided into a first space between the upper electrode and the shower head and a second space disposed below the shower head. The shower head may have a plurality of openings formed therethrough to allow the first space and the second space to communicate with each other. The substrate support may be configured to support a substrate in the second space. The shielding part may be disposed between the upper electrode and the shower head. The shielding part may include a first shielding plate and a second shielding plate arranged in parallel along the shower head. The second shielding plate may be disposed over the shower head. The first shielding plate may be disposed over the second shielding plate. Each of the first shielding plate and the second shielding plate may have a plurality of through-holes arranged to be aligned with the openings of the shower head. The gas supply device may be configured to supply a gas to a region between the upper electrode and the shielding part in the first space. The radio frequency (RF) power supply may be configured to output an RF voltage to generate plasma of the gas. The voltage applying part may be configured to select ions or radicals passing through the through-holes in the plasma by applying a control voltage to the shielding part. The controller may be configured to control the voltage applying part. The voltage applying part may be configured to independently apply a control voltage to each of the first shield plate and the second shield plate depending on control from the controller.

The control voltage can be independently applied to each of the first shielding plate and the second shielding plate. Therefore, it is possible to select the type of particles (positive ions, negative ions, electrons, or radicals) passing through the shielding part and the shower head in the plasma produced in the space between the upper electrode and the shielding part in the first region.

In an exemplary embodiment, each of the first shielding plate and the second shielding plate may include a metal plate having insulating coating. The voltage applying part may include a first pulse generator, a second pulse generator, a first variable DC power supply, and a second variable DC power supply. The first pulse generator and the second pulse generator are configured to output rectangular-wave control voltages. The first shielding plate, the first pulse generator, and the first variable DC power supply may be electrically connected in series in that order. The second shielding plate, the second pulse generator, and the second variable DC power supply may be electrically connected in series in that order. The controller may control the voltage applying part to apply rectangular-wave control voltages having opposite phases to the first shielding plate and the second shielding plate.

In an exemplary embodiment, each of the first shielding plate and the second shielding plate may include a metal plate having no insulation coating. The voltage applying part may include a first variable DC power supply and a second variable DC power supply. The first shield plate and the first variable DC power supply may be electrically connected in series. The second shield plate and the second variable DC power supply may be electrically connected in series. The controller controls the voltage applying part to apply a DC control voltage to each of the first shield plate and the second shield plate.

In an exemplary embodiment, the controller may control the voltage applying part such that an absolute value of the control voltage applied to the second shielding plate is greater than or equal to an absolute value of the control voltage applied to the first shielding plate.

In an exemplary embodiment, the plasma processing apparatus may further comprises an electric circuit electrically connected to the RF power supply. The RF power supply may be electrically connected to the upper electrode and generate plasma of the gas by applying an RF voltage to the upper electrode. The electric circuit may have a diode electrically connected between the RF power supply and the ground. An anode of the diode may be electrically connected to the RF power supply. A cathode of the diode may be electrically connected to the ground.

In an exemplary embodiment, the plasma processing apparatus may further comprises a coil and an electric circuit. The coil may be electrically connected to the RF power supply and extend along the upper electrode on the upper electrode. The electric circuit may be electrically connected to the RF power supply through the coil. The RF power supply may generate plasma of the gas by applying an RF voltage to the coil. The electric circuit may have a capacitor electrically connected between the RF power supply and the ground.

In an exemplary embodiment, a plasma processing method, performed by a plasma processing apparatus, for processing a substrate is provided. The plasma processing apparatus includes a shower head, a shielding part, and a radio frequency (RF) power supply. The shower head may be disposed below an upper electrode. An inner space of a chamber may be divided into a first space between the upper electrode and the shower head and a second space disposed below the shower head. The shower head may have a plurality of openings formed therethrough to allow the first space and the second space to communicate with each other. The shielding part may be disposed between the upper electrode and the shower head. The shielding part may include a first shielding plate and a second shielding plate arranged in parallel along the shower head. The second shielding plate may be disposed over the shower head. The first shielding plate may be disposed over the second shielding plate. Each of the first shielding plate and the second shielding may have a plurality of through-holes arranged to be aligned with the openings of the shower head. The radio frequency (RF) power supply may be configured to output an RF voltage to produce plasma of a gas supplied from a gas supply device to a region in the first space. The method comprises steps A, B, C and D. In step A, a substrate may be prepared on a substrate support configured to support a substrate in the second space. In step B, an RF voltage may be applied to the upper electrode. In step C, plasma may be generated in a space between the upper electrode and the shielding part by the RF voltage. In step D, a control voltage may be applied to the shielding part in order to select ions or radicals passing through the through-holes in the plasma. In step D, the control voltage may be independently applied to each of the first shielding plate and the second shielding plate.

The control voltage can be independently applied to each of the first shielding plate and the second shielding plate. Therefore, it is possible to select the type of particles (any one of positive ions, negative ions, electrons, and radicals) passing through the shielding part and the shower head in the plasma produced in the space of the first region between the upper electrode and the shielding part.

Hereinafter, various embodiments will be described in detail with reference to the accompanying drawings. Like reference numerals will be given to like or corresponding parts throughout the drawings.

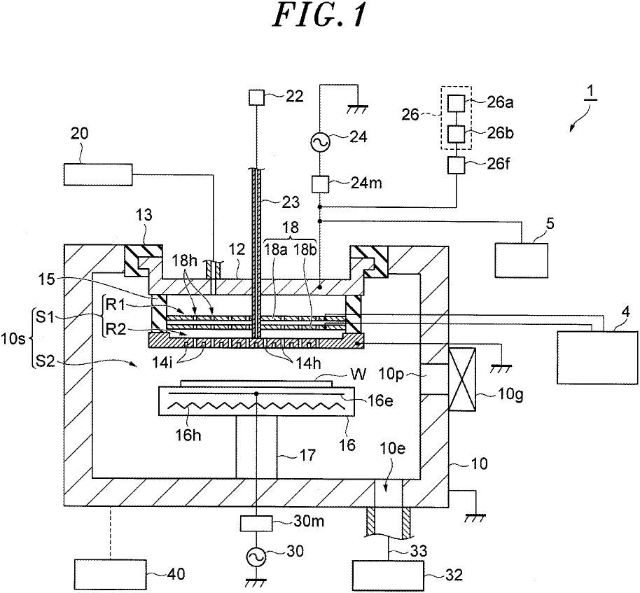

FIG. 1 schematically shows a plasma processing apparatus according to one embodiment. A plasma processing apparatus 1 shown in FIG. 1 is a capacitively coupled plasma (CCP) plasma processing apparatus, and includes a chamber 10. The chamber 10 has a substantially cylindrical shape, and is made of a conductive material such as aluminum or the like. The chamber 10 is grounded, and has an inner space 10s.

The plasma processing apparatus 1 further includes an upper electrode 12. The upper electrode 12 extends above a substrate support 16 to be described later. In one embodiment, the upper electrode 12 closes an upper opening of the chamber 10 together with a member 13. The upper electrode 12 has a substantially disc shape, and is made of a conductive material such as aluminum or the like. The member 13 is made of an insulating material. The member 13 is interposed between the upper end of the chamber 10 and the upper electrode 12.

The plasma processing apparatus 1 further includes a shower head 14. The shower head 14 is disposed below the upper electrode 12. The shower head 14 has a substantially disc shape. The shower head 14 is made of a conductive material such as aluminum. The shower head 14 divides the inner space 10s into a space S1 and a space S2. The space S1 is disposed between the upper electrode 12 and the shower head 14. The space S2 is disposed below the shower head 14.

In one embodiment, a member 15 may be disposed between the upper electrode 12 and the shower head 14. The member 15 has a cylindrical shape, and is made of an insulating material such as aluminum oxide. The space S1 is disposed between the upper electrode 12 and the shower head 14, and is disposed inside the member 15.

The shower head 14 has a plurality of inlets 14i and a plurality of openings 14h. The inlets 14i are formed in the shower head 14 to introduce a gas into the space S2. The openings 14h are formed in the shower head 14 to allow the space S1 and the space S2 to communicate with each other.

The chamber 10 has a sidewall. The sidewall of chamber 10 defines a passage 10p. The substrate W is transferred between the space S2 and the outside of the chamber 10 through the passage 10p. The plasma processing apparatus 1 may further include a gate valve 10g. The gate valve 10g is disposed along the sidewall of the chamber 10 to open and close the passage 10p.

The plasma processing apparatus 1 further includes the substrate support 16. The substrate support 16 is configured to support the substrate W in the space S2. The substrate W may have a substantially disc shape. The substrate W is processed while being placed on the substrate support 16 in the space S2. The substrate support 16 may be made of an insulating ceramic such as aluminum nitride. Alternatively, substrate support 16 may be made of a conductive material.

In one embodiment, the substrate support 16 may be supported by a support member 17. The support member 17 may extend upward from the bottom portion of the chamber 10. The substrate support 16 may have a heater 16h. The heater 16h is disposed in the substrate support 16. The heater 16h is configured to receive a power supplied from a heater power supply. The heater 16h is configured to heat the substrate W on the substrate support 16 to a specific temperature.

In one embodiment, the substrate support 16 may further include a lower electrode 16e. The lower electrode 16e is disposed in the substrate support 16. When the substrate support 16 is made of a conductive material, the substrate support 16 functions as the lower electrode 16e.

The plasma processing apparatus 1 further includes a gas supply device 20. The gas supply device 20 is configured to supply a gas to the region in the space S1 between the upper electrode 12 and a shielding part 18, particularly to a region R1. In one embodiment, the gas supply device 20 is connected to a gas inlet port of the upper electrode 12, and supplies a gas to the region R1 through the gas inlet port.

The plasma processing apparatus 1 further includes a gas supply device 22. The gas supply device 22 is configured to supply a gas to the shower head 14. In one embodiment, the gas supply device 22 is connected to the shower head 14 through a line 23, and supplies a gas to the shower head 14 through the line 23. The gas supplied from the gas supply device 22 to the shower head 14 is introduced into the space S2 through the inlets 14i communicating with each other in the shower head 14.

The plasma processing apparatus 1 includes one or more power supplies to produce plasma from a gas in the chamber 10. One or more power supplies are connected to the upper electrode 12. In one embodiment, the plasma processing apparatus 1 may include a radio frequency (RF) power supply 24 and a DC pulse power supply 26 as one or more power supplies.

The RF power supply 24 is configured to output an RF voltage (hereinafter, may be referred to as “first RF voltage”) to generate plasma of the gas supplied from the gas supply device 20 to the region R1. The RF power supply 24 is connected to the upper electrode 12. The first RF voltage is supplied to the upper electrode 12. The first RF voltage may have a frequency higher than or equal to 300 kHz and lower than or equal to 100 MHz. In one example, the frequency of the first RF voltage may be 40 MHz.

The RF power supply 24 may be connected to the upper electrode 12 through a matching device 24m. The matching device 24m includes a matching circuit for matching an impedance on a load side of the RF power supply 24 with an output impedance of the RF power supply 24. Hereinafter, the RF power supply 24 and the matching device 24m may be collectively referred to as “RF power supply.”

The DC pulse power supply 26 intermittently or periodically generates a pulsed DC voltage. The DC pulse power supply 26 is connected to the upper electrode 12. The pulsed DC voltage generated by the DC pulse power supply 26 is applied to the upper electrode 12. The pulsed DC voltage may have a positive polarity, or may have a negative polarity. The frequency that determines the period of the pulsed DC voltage applied to the upper electrode 12 is higher than or equal to 10 Hz and lower than or equal to 1 MHz. This frequency is the reciprocal of the period of the pulsed DC voltage applied to the upper electrode 12. In one example, this frequency may be 500 kHz.

In one embodiment, the DC pulse power supply 26 may include a DC power supply 26a and a pulse unit 26b. The DC power supply 26a generates a DC voltage. The DC power supply 26a may be a variable DC power supply. The pulse unit 26b is connected between the DC power supply 26a and the upper electrode 12. The pulse unit 26b is configured to modulate the DC voltage from the DC power supply 26a into a pulsed DC voltage. The pulse unit 26b may include one or more switching transistors.

In one embodiment, the DC pulse power supply 26 may be connected to the upper electrode 12 through a filter 26f. The filter 26f is an electrical filter for blocking or attenuating an RF voltage.

In one embodiment, the plasma processing apparatus 1 may further include an RF power supply 30. The RF power supply 30 generates an RF voltage (hereinafter, may be referred to as “second RF voltage”). The RF power supply 30 is connected to the lower electrode 16e. The second RF voltage is supplied to the lower electrode 16e. The frequency of the second RF voltage is higher than or equal to 300 kHz and lower than or equal to 100 MHz. In one example, the frequency of the second RF voltage may be 400 kHz.

The RF power supply 30 may be connected to the lower electrode 16e via a matching device 30m. The matching device 30m includes a matching circuit for matching an impedance on a load side of the RF power supply 30 with an output impedance of the RF power supply 30.

In one embodiment, the plasma processing apparatus 1 may further include an exhaust device 32. The exhaust device 32 is connected to the inner space 10s of the chamber 10 through an exhaust line 33. The exhaust device 32 may include one or more pumps such as a dry pump or a turbo molecular pump, and a pressure controller such as an automatic pressure control valve. In one embodiment, the exhaust device 32 may be connected to the space S2 through the exhaust line 33 and an exhaust port 10e. The exhaust port 10e may be disposed at the bottom portion of the chamber 10.

In one embodiment, the plasma processing apparatus 1 may further include a controller 40. The controller 40 is configured to control individual components of the plasma processing apparatus 1, such as a voltage applying part 4 and the like. The controller 40 may be a computer having a processor, an input device, an output device, a display device, a storage device, and the like. The storage device stores a control program and recipe data. The processor executes the control program and controls the individual components of the plasma processing apparatus 1 based on the recipe data. Accordingly, the plasma processing apparatus 1 performs plasma processing based on the recipe data. Plasma processing methods according to various embodiments to be described later can be performed in the plasma processing apparatus 1 by controlling the individual components of the plasma processing apparatus 1 under the control of the controller 40.

The plasma processing apparatus 1 further includes a shielding part 18. The shielding part 18 is disposed between the upper electrode 12 and the shower head 14. The shielding part 18 divides the space S1 into a region R1 and a region R2. The region R1 is disposed between the upper electrode 12 and the shielding part 18. The region R2 is disposed between the shielding part 18 and the shower head 14.

The shielding part 18 has a plurality of through-holes 18h. The through-holes 18h are arranged to be aligned with the openings 14h, respectively. That is, the through-holes 18h are arranged such that the lower ends thereof face the upper ends of the openings 14h, respectively. In other words, the through-holes 18h and the openings 14h are arranged to overlap each other over the plane parallel to the substrate W.

The shielding part 18 has a shielding plate 18a and a shielding plate 18b arranged in parallel along the shower head 14. The shielding plate 18b is disposed above the shower head 14, and the shielding plate 18a is disposed above the shielding plate 18b. The shielding plates 18a and 18b have the through-holes 18h arranged to be respectively aligned with the openings 14h of the shower head 14.

Both the shielding plates 18a and 18b may include a metal plate (e.g., a metal plate made of pure aluminum, nickel, or the like) having no insulation coating. Each of the shielding plates 18a and 18b may include a metal plate (e.g., a metal plate made of pure aluminum, nickel, or the like) having insulating coating (e.g., having a non-conductive surface formed by alumite treatment or thermal spraying). The shielding part 18 has a substantially disc shape. In one embodiment, the inner wall surface of the chamber 10, the surface of the upper electrode 12, the surface of the shower head 14, and the surface of the shielding part 18 may be covered with a corrosion-resistant film. The corrosion-resistant film may be an alumite film or an yttrium oxide film.

The plasma processing apparatus 1 may further include the voltage applying part 4. The voltage applying part 4 is configured to select ions or radicals passing through the through-holes 18h in the plasma produced in the region R1 of the space S1 by applying a control voltage to the shielding part 18. The voltage applying part 4 is configured to independently apply a control voltage to each of the shielding plates 18a and 18b depending on the control from the controller 40.

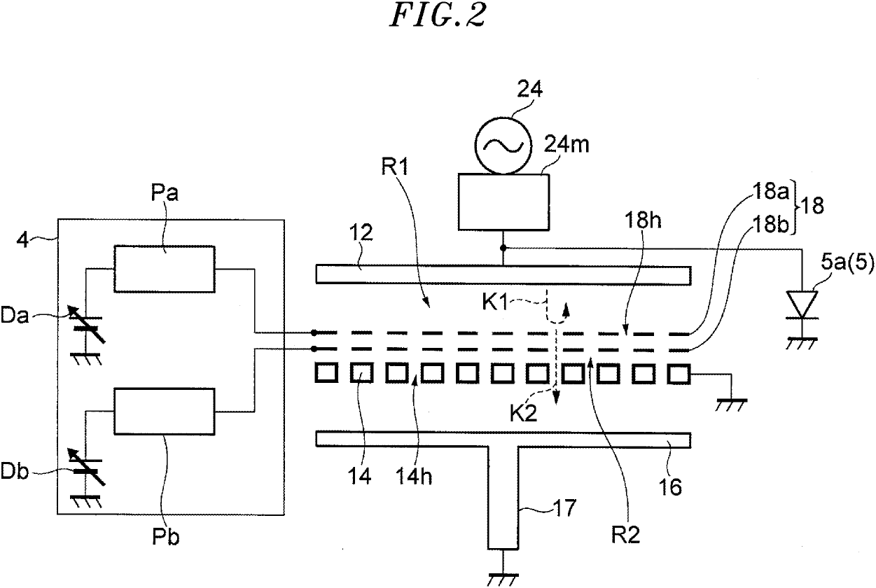

FIG. 2 shows an example of a partial configuration of the plasma processing apparatus 1 in the case where both the shielding plates 18a and 18b include metal plates having insulation coating. FIG. 2 shows a schematic configuration for convenience of description. In one embodiment, the voltage applying part 4 includes a pulse generator Pa, a pulse generator Pb, a variable DC power supply Da, and a variable DC power supply Db. The shielding plate 18a, the pulse generator Pa, and the variable DC power supply Da are electrically connected in series in that order. The shielding plate 18b, the pulse generator Pb, and the variable DC power supply Db are electrically connected in series in that order. The controller 40 controls the voltage applying part 4 to apply rectangular-wave control voltages having opposite phases to the shielding plates 18a and 18b.

In one embodiment, both the pulse generators Pa and Pb of the voltage applying part 4 shown in FIG. 2 are configured to output rectangular-wave control voltages. The controller 40 controls the voltage applying part 4 to respectively apply the rectangular-wave control voltages having the same frequency and opposite phases to the shielding plates 18a and 18b. Both the pulse generators Pa and Pb can output rectangular-wave (pulsed) control voltages having the same frequency within the range of 0 MHz to 1 MHz and opposite phases.

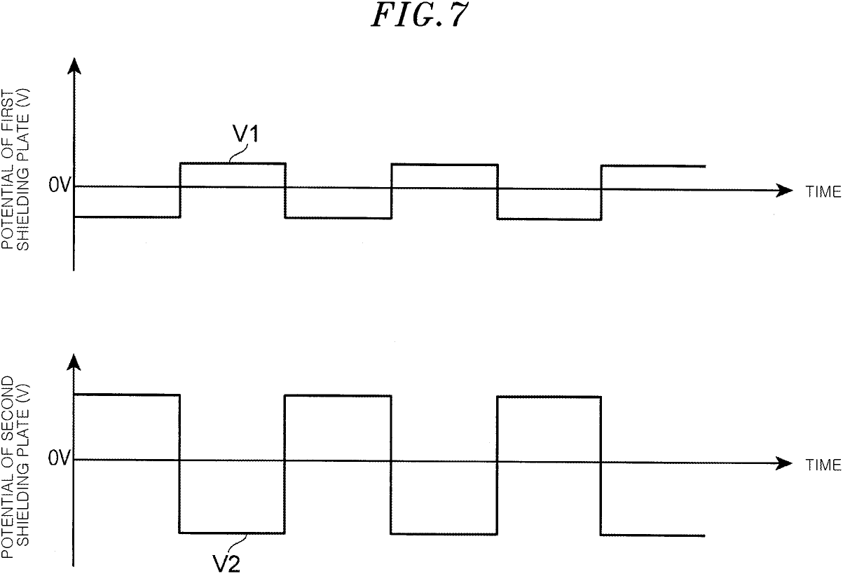

The rectangular-wave control voltages having opposite phases are applied to the shielding plates 18a and 18b. Accordingly, as shown in FIG. 7, a potential V1 of the shielding plate 18a and a potential V2 of the shielding plate 18b become rectangular-wave potentials having the same frequency and opposite phases, similarly to the control voltages.

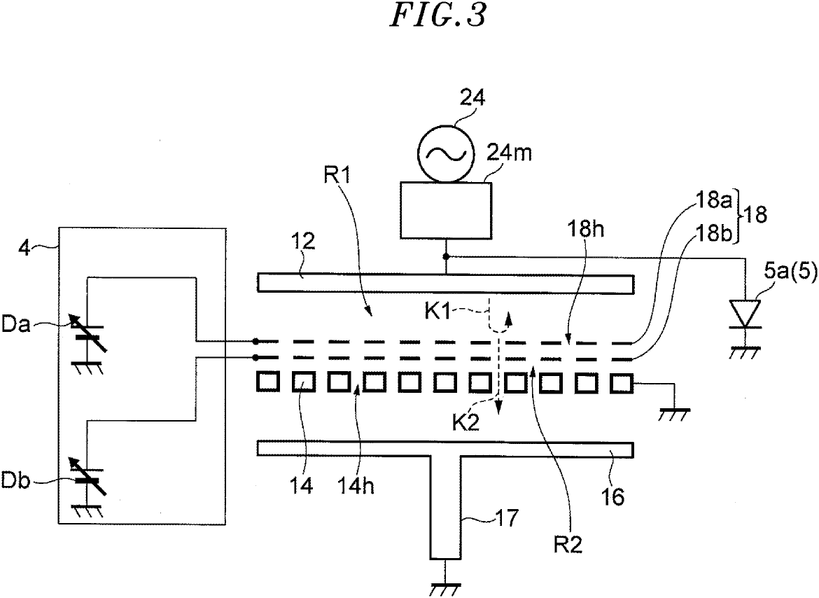

As shown in FIG. 7, when the potential V1 of the shielding plate 18a is positive and the potential V2 of the shielding plate 18b is negative, positive ions stay in the region R1 along a direction K1 of FIG. 3 without passing through the through-holes 18h in the shielding plate 18a. In this case, negative ions and electrons pass through the through-holes 18h in the shielding plate 18a along a direction K2 of FIG. 3, but stay in the region R1 along the direction K1 of FIG. 3 without passing through the through-holes 18h in the shielding plate 18b. When the potential V1 of the shielding plate 18a is negative and the potential V2 of the shielding plate 18b is positive, negative ions and electrons stay in the region R1 along the direction K1 of FIG. 3 without passing through the through-holes 18h in the shielding plate 18a. In this case, positive ions pass through the through-holes 18h in the shielding plate 18a along the direction K2 of FIG. 3, but stay in the region R1 along the direction K1 of FIG. 3 without passing through the through-holes 18h in the shielding plate 18b. Therefore, as shown in FIG. 7, when the potential V1 of the shielding plate 18a and the potential V2 of the shielding plate 18b are rectangular-wave potentials having opposite phases, radicals in the plasma produced in the region R1 may selectively pass through the through-holes 18h.

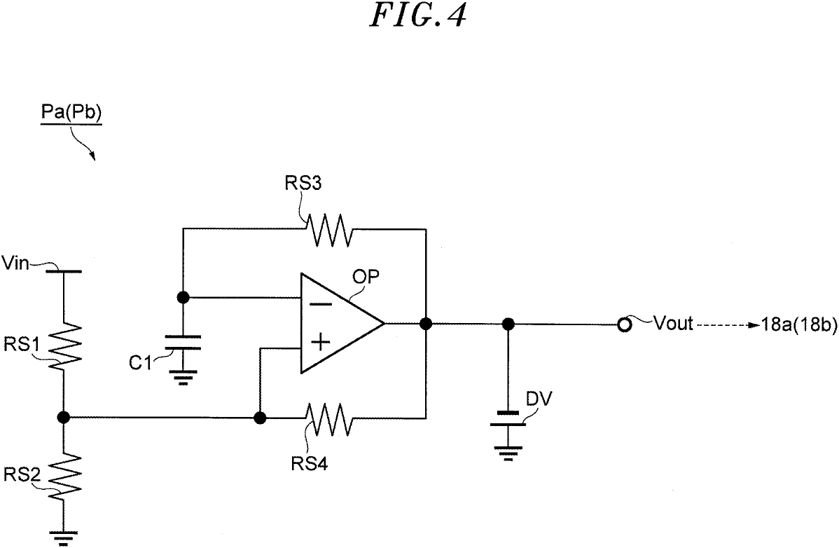

In one embodiment, both the pulse generator Pa and the pulse generator Pb may have the circuit configuration shown in FIG. 4. Each of the pulse generator Pa and the pulse generator Pb has an input terminal Vin, a resistor RS1, a resistor RS2, an amplifier OP, a resistor RS3, a resistor RS4, a capacitor C1, a DC power supply DV, and an output terminal Vout. The input terminal Vin, the resistor RS1, and the resistor RS2 are electrically connected in series in that order, and the resistor RS2 is electrically connected to the ground. The connection point of the resistor RS1 and the resistor RS2 is electrically connected to a positive input terminal of the amplifier OP and electrically connected to the output terminal of the amplifier OP through the resistor RS4. The negative input terminal of amplifier OP is electrically connected to the output terminal of the amplifier OP through the resistor RS3, and also electrically connected to the ground through the capacitor C1.

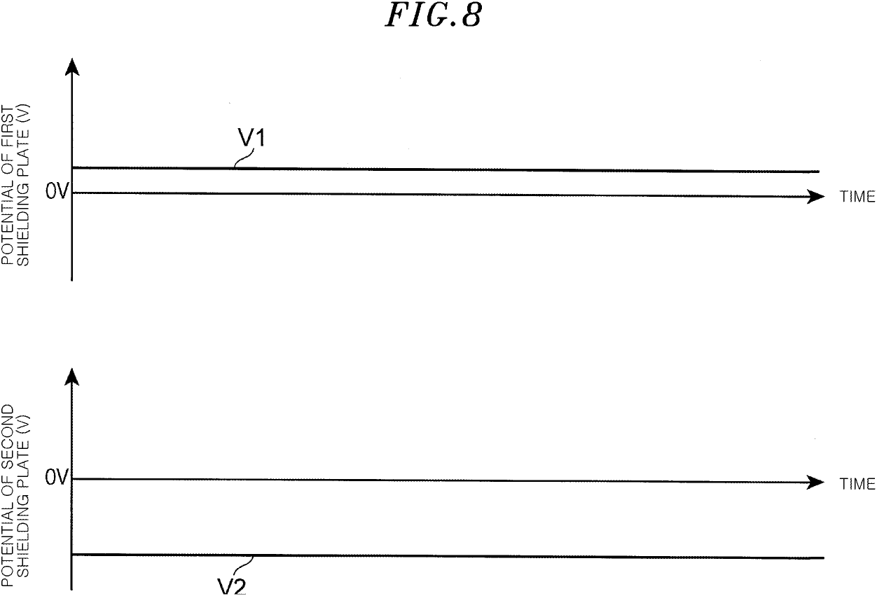

The controller 40 controls the voltage applying part 4 such that an absolute value of the control voltage applied to the shielding plate 18b becomes greater than or equal to an absolute value of the control voltage applied to the shielding plate 18a. Accordingly, charged particles that have unintentionally passed through the through-holes 18h in the shielding plate 18a can be prevented from further passing through the through-holes 18h in the shielding plate 18b. The absolute value of the potential V2 shown in each of FIGS. 8, 9, 10, and 11 is also greater than or equal to the absolute value of the potential V1 shown in each of FIGS. 8, 9, 10, and 11.

FIG. 3 shows an example of a partial configuration of the plasma processing apparatus 1 in the case where both the shielding plate 18a and the shielding plate 18b include metal plates (pure metal plates) having no insulation coating. FIG. 3 shows a schematic configuration for convenience of description. In one embodiment, the voltage applying part 4 includes a variable DC power supply Da and a variable DC power supply Db. The shielding plate 18a and the variable DC power supply Da are electrically connected in series in that order. The shielding plate 18b and the variable DC power supply Db are electrically connected in series in that order. The controller 40 controls the voltage applying part 4 to apply a DC control voltage to each of the shielding plate 18a and the shielding plate 18b.

In one embodiment, both the variable DC power supply Da and the variable DC power supply Db of the voltage applying part 4 shown in FIG. 3 are configured to apply DC control voltages. The controller 40 controls the voltage applying part 4 to apply a DC control voltage to each of the shielding plate 18a and the shielding plate 18b.

By applying a DC control voltage to each of the shielding plate 18a and the shielding plate 18b, the potential V1 of the shielding plate 18a and the potential V2 of the shielding plate 18b becomes a constant potential similarly to the control voltage, as shown in each of FIGS. 8, 9, 10, and 11.

As shown in FIG. 8, when the potential V1 of the shielding plate 18a is positive and the potential V2 of the shielding plate 18b is negative, positive ions stay in the region R1 along the direction K1 of FIG. 3 without passing through the through-holes 18h of the shielding plate 18a. In this case, negative ions and electrons pass through the through-holes 18h in the shielding plate 18a along the direction K2 of FIG. 3, but stay in the region R1 along the direction K1 of FIG. 3 without passing through the through-holes 18h in the shielding plate 18b. Therefore, when the potential V1 of the shielding plate 18a is positive and the potential V2 of the shielding plate 18b is negative as shown in FIG. 8, radicals in plasma produced in the region R1 can selectively pass through the through-holes 18h.

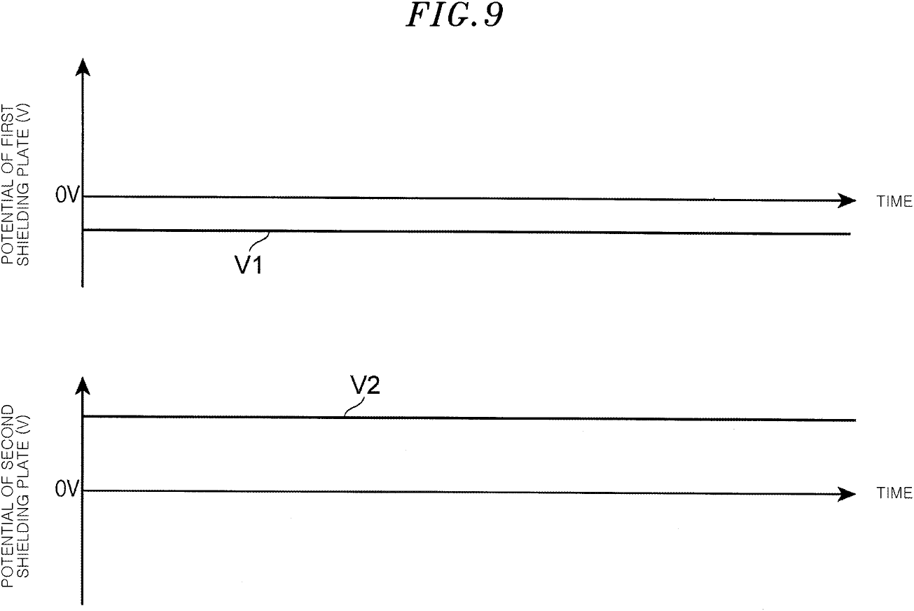

As shown in FIG. 9, when the potential V1 of the shielding plate 18a is negative and the potential V2 of the shielding plate 18b is positive, negative ions and electrons stay in the region R1 along the direction K1 of FIG. 3 without passing through the through-holes 18h. In this case, positive ions pass through the through-holes 18h in the shielding plate 18a along the direction K2 of FIG. 3, but stay in the region R1 along the direction K1 of FIG. 3 without passing through the through-holes 18h in the shielding plate 18b. Therefore, when the potential V1 of the shielding plate 18a is negative and the potential V2 of the shielding plate 18b is positive as shown in FIG. 9, radicals in the plasma produce in the region R1 can selectively pass through the through-holes 18h.

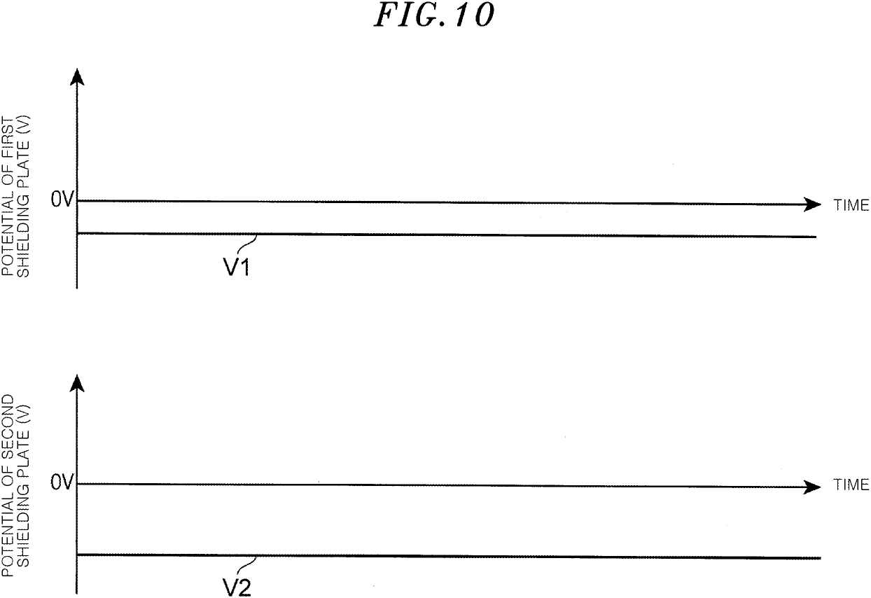

As shown in FIG. 10, when the potential V1 of the shielding plate 18a and the potential V2 of the shielding plate 18b are negative, positive ions pass through the through-holes 18h along the direction K2 of FIG. 3. In this case, the negative ions and electrons stay in the region R1 along the direction K1 of FIG. 3 without passing through the through-holes 18h in the shielding plate 18a and the shielding plate 18b (the shielding part 18). Therefore, when the potential V1 of the shielding plate 18a and the potential V2 of the shielding plate 18b are negative as shown in FIG. 10, positive ions and radicals in the plasma produced in the region R1 can selectively pass through the through-holes 18h.

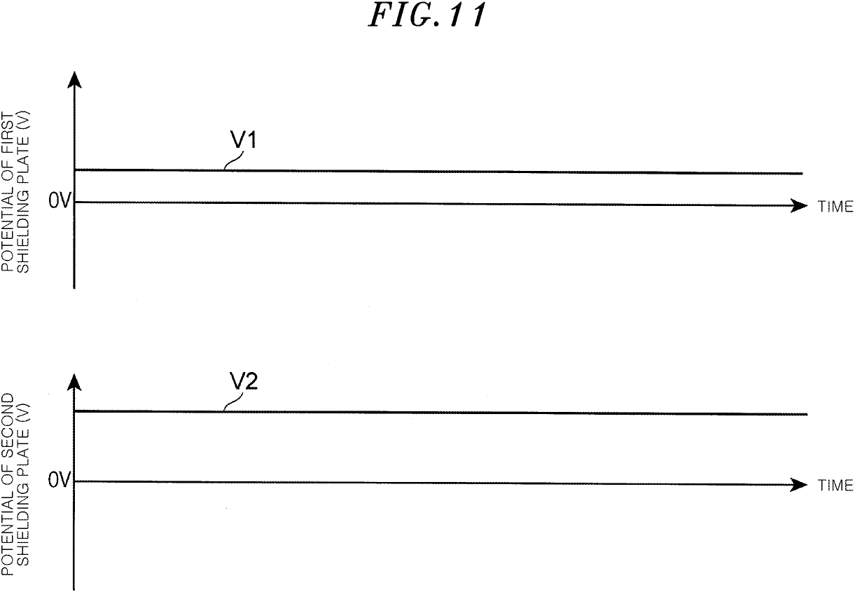

When the potential V1 of the shielding plate 18a and the potential V2 of the shielding plate 18b are positive as shown in FIG. 11, negative ions and electrons pass through the through-holes 18h in the shielding plates 18a and 18b (the shielding part 18) along the direction K2 of FIG. 3. In this case, the positive ions stay in the region R1 along the direction K1 of FIG. 3 without passing through the through-holes 18h in the shielding plates 18a and 18b (the shielding part 18). Therefore, when the potential V1 of the shielding plate 18a and the potential V2 of the shielding plate 18b are positive as shown in FIG. 11, negative ions and radicals in the plasma produced in the region R1 can selectively pass through the through-holes 18h.

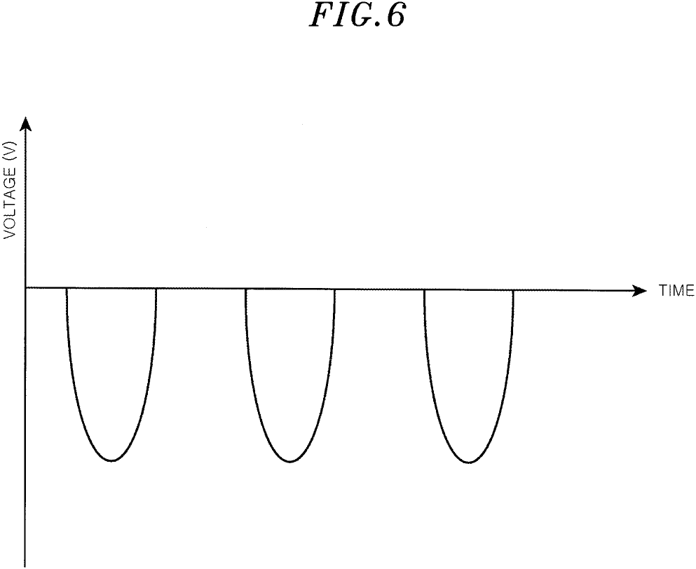

In one embodiment, the plasma processing apparatus 1 may further include an electric circuit 5. As shown in FIGS. 1 to 3, when the plasma processing apparatus 1 is a capacitively coupled plasma processing apparatus, the electric circuit 5 has a diode 5a electrically connected between the RF power supply 24 and the ground. The anode of the diode 5a is electrically connected to the RF power supply 24, and the cathode of the diode 5a is electrically connected to the ground. The electric circuit 5 is electrically connected to the RF power supply 24 through a matching device 24m. The RF power supply 24 is electrically connected to the upper electrode 12, and configured to apply an RF voltage to the upper electrode 12 to generate plasma of the gas supplied from the gas supply device 20 to the region R1 of the space S1. As shown in FIG. 6, a positive voltage is removed, and only a negative voltage is applied from the RF power supply 24 to the upper electrode 12 by the electric circuit 5 having the diode 5a. Accordingly, the energy of positive ions traveling toward the shielding part 18 becomes almost 0 eV, and the potential of each of the shielding plates 18a and 18b for trapping positively charged particles such as ions and the like may be about +10 V. When the electric circuit 5 is not provided, the potential of each of the shielding plates 18a and 18b for trapping charged particles such as ions and the like is within the range of ±5 V to ±500 V.

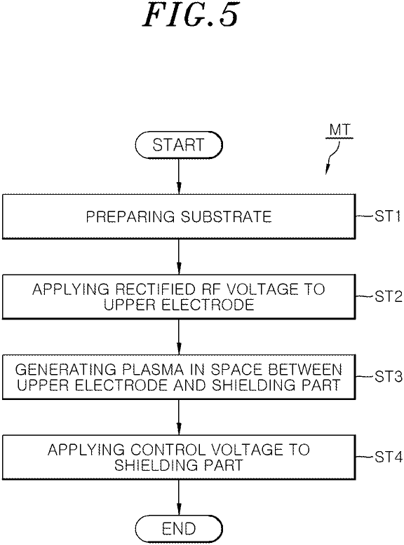

FIG. 5 is a flowchart of a plasma processing method (method MT) in one embodiment. The method MT includes steps ST1 to ST4. In the step ST1, the substrate W is prepared on the substrate support 16 configured to support a substrate in the space S2. In the step ST2 executed after the step ST1, an RF voltage is applied from the RF power supply 24 to the upper electrode 12. In the step ST3 executed after the step ST2, plasma of the gas supplied from the gas supply device 20 is generated in the space between the upper electrode 12 and the shielding part 18 by the RF voltage applied from the RF power supply 24 to the upper electrode 12. In the step ST4 executed after the step ST3, the control voltage is applied to the shielding part 18 in order to select ions or radicals passing through the through-holes 18h in the plasma. In the step ST4, the control voltage is independently applied to each of the shielding plates 18a and 18b. Accordingly, it is possible to select ions or radicals passing through the through-holes 18h of the shielding part 18 in the plasma produced in the region R1 of the space S1.

As described above, by controlling the potentials of the shielding plates 18a and 18b, it is possible to properly select the type of particles (between positively charged particles and negatively charged particles) passing through the through-holes 18h of the shielding part 18 and attracted to the substrate W in the plasma produced in the region R1.

For example, by setting the shielding plates 18a and 18b to have potentials having different polarities, radicals can be selected as particles passing through the through-holes 18h of the shielding part 18 and attracted to the substrate W. Accordingly, processing using radicals can be performed.

For example, by setting the shielding plates 18a and 18b to have potentials having the same polarity, particles passing through the through-holes 18h of the shielding part 18 and attracted to the substrate W can be selected among positive ions, negative ions, and electrons. Accordingly, anisotropic processing using ions cab be performed.

While various embodiments have been described above, the present disclosure is not limited to the above-described embodiments, and various additions, omissions, substitutions and changes may be made. Further, other embodiments can be implemented by combining elements in different embodiments.

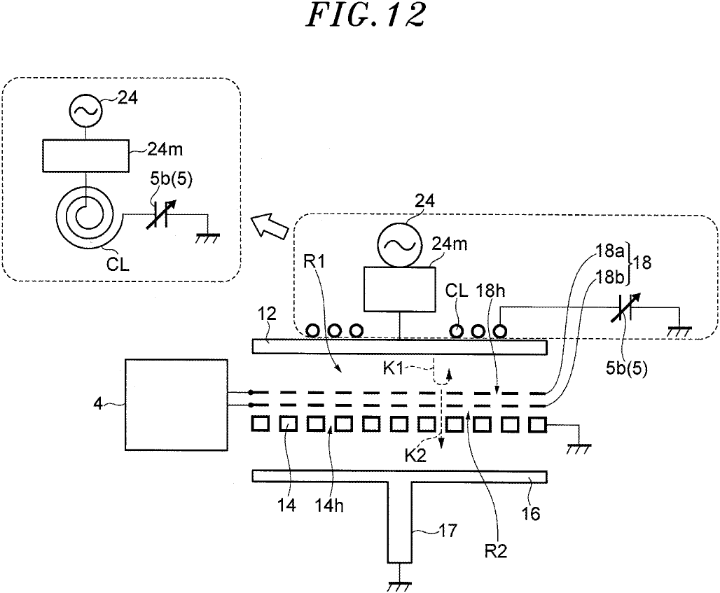

For example, the plasma processing apparatus 1 according to one embodiment is not limited to the capacitively coupled (CCP) plasma processing apparatus shown in FIGS. 1 to 3. For example, the plasma processing apparatus 1 may be an inductively coupled plasma (ICP) plasma processing apparatus shown in FIG. 12. FIG. 12 shows a schematic configuration for convenience of description. As shown in FIG. 12, the inductively coupled plasma processing apparatus 1 includes a coil CL and the electric circuit 5. The coil CL is electrically connected to the RF power supply 24 through the matching device 24 m, and extends along the upper electrode 12 on the upper electrode 12. The electric circuit 5 is electrically connected to the RF power supply 24 through the coil CL and the matching device 24m. The RF power supply 24 is configured to produce plasma of the gas supplied from the gas supply device 20 to the region R1 of the space S1 by applying an RF voltage to the coil CL. The electric circuit 5 has a capacitor 5b electrically connected between the RF power supply 24 (including the matching device 24m) and the ground. The inductively coupled plasma processing apparatus 1 shown in FIG. 12 can perform the same functions as those of the capacitively coupled plasma processing apparatus 1, and can achieve the same effects as those of the capacitively coupled plasma processing apparatus 1. The plasma source can be applied to microwaves other than CCP and ICP.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus comprising:
a chamber;
an upper electrode;
a shower head disposed below the upper electrode, an inner space of the chamber being divided into a first space between the upper electrode and the shower head and a second space disposed below the shower head, the shower head having a plurality of openings formed therethrough to allow the first space and the second space to communicate with each other;
a substrate support configured to support a substrate in the second space;
a shielding part disposed between the upper electrode and the shower head, the shielding part including a first shielding plate and a second shielding plate arranged in parallel along the shower head, the second shielding plate being disposed over the shower head, the first shielding plate being disposed over the second shielding plate, each of the first shielding plate and the second shielding plate having a plurality of through-holes arranged to be aligned with the openings of the shower head;
a gas supply device configured to supply a gas to a region between the upper electrode and the shielding part in the first space;
a radio frequency (RF) power supply configured to output an RF voltage to generate plasma of the gas;
a voltage applying part configured to select ions or radicals passing through the through-holes in the plasma by applying a control voltage to the shielding part; and
a controller configured to control the voltage applying part;
wherein the voltage applying part is configured to independently apply a control voltage to each of the first shield plate and the second shield plate depending on control from the controller.

2. The plasma processing apparatus of claim 1, wherein each of the first shielding plate and the second shielding plate includes a metal plate having insulating coating,
the voltage applying part includes a first pulse generator, a second pulse generator, a first variable DC power supply, and a second variable DC power supply,
wherein the first pulse generator and the second pulse generator are configured to output rectangular-wave control voltages,
the first shielding plate, the first pulse generator, and the first variable DC power supply are electrically connected in series in that order,
the second shielding plate, the second pulse generator, and the second variable DC power supply are electrically connected in series in that order, and
the controller controls the voltage applying part to apply rectangular-wave control voltages having opposite phases to the first shielding plate and the second shielding plate.

3. The plasma processing apparatus of claim 1, wherein each of the first shielding plate and the second shielding plate includes a metal plate having no insulation coating,
the voltage applying part includes a first variable DC power supply and a second variable DC power supply,
the first shield plate and the first variable DC power supply are electrically connected in series,
the second shield plate and the second variable DC power supply are electrically connected in series, and
the controller controls the voltage applying part to apply a DC control voltage to each of the first shield plate and the second shield plate.

4. The plasma processing apparatus of claim 1, wherein the controller controls the voltage applying part such that an absolute value of the control voltage applied to the second shielding plate is greater than or equal to an absolute value of the control voltage applied to the first shielding plate.

5. The plasma processing apparatus of claim 1, further comprising:
an electric circuit electrically connected to the RF power supply,
wherein the RF power supply is electrically connected to the upper electrode and generates plasma of the gas by applying an RF voltage to the upper electrode,
the electric circuit has a diode electrically connected between the RF power supply and the ground, and
an anode of the diode is electrically connected to the RF power supply, and a cathode of the diode is electrically connected to the ground.

6. The plasma processing apparatus of claim 1, further comprising:
a coil electrically connected to the RF power supply and extending along the upper electrode on the upper electrode; and
an electric circuit electrically connected to the RF power supply through the coil,
wherein the RF power supply generates plasma of the gas by applying an RF voltage to the coil, and
the electric circuit has a capacitor electrically connected between the RF power supply and the ground.

7. A plasma processing method, performed by a plasma processing apparatus, for processing a substrate, the plasma processing apparatus including a shower head disposed below an upper electrode, an inner space of a chamber being divided into a first space between the upper electrode and the shower head and a second space disposed below the shower head, the shower head having a plurality of openings formed therethrough to allow the first space and the second space to communicate with each other, a shielding part disposed between the upper electrode and the shower head, the shielding part including a first shielding plate and a second shielding plate arranged in parallel along the shower head, the second shielding plate being disposed over the shower head, the first shielding plate being disposed over the second shielding plate, each of the first shielding plate and the second shielding having a plurality of through-holes arranged to be aligned with the openings of the shower head, and a radio frequency (RF) power supply configured to output an RF voltage to produce plasma of a gas supplied from a gas supply device to a region in the first space, the method comprising:
preparing a substrate on a substrate support configured to support a substrate in the second space;
applying an RF voltage to the upper electrode;
generating plasma in a space between the upper electrode and the shielding part by the RF voltage; and
applying a control voltage to the shielding part in order to select ions or radicals passing through the through-holes in the plasma,
wherein in said applying the control voltage, the control voltage is independently applied to each of the first shielding plate and the second shielding plate.
